(19) United States
(12) Patent Application Publication
(10) Pub. No.: US 2013/0045548 A1
(43) Pub. Date: Feb. 21, 2013

(54) Apparatus and method for simultaneous deposition of a plurality of semiconductor layers in a plurality of process chambers

(71) Applicants: Johannes Käppeler, Wurselen (DE); Adam Boyd, Kelmis (BE)

(72) Inventors: Johannes Käppeler, Wurselen (DE); Adam Boyd, Kelmis (BE)

(21) Appl. No.: 13/641,437

(22) PCT Filed: Apr. 16, 2011
(86) PCT No.: PCT/EP2011/055248

§ 371 Date: Nov. 8, 2012

(30) Foreign Application Priority Data
Apr. 16, 2010 (DE) 10 2010 016 471.2

(51) Int. Cl. H01L 21/20; H01L 21/66

(52) U.S. Cl. 438/16; 118/712; 257/E21.53

(57) ABSTRACT

A method for depositing a semiconductor layer on a multiplicity of substrates. The process chamber height (H), which is defined by the spacing between a process chamber ceiling (8) and a process chamber floor (9) is variable and influences the growth rate of the layer. The layer thickness is measured continuously or at in short intervals on at least one substrate (5) in each process chamber (2) while the layer is growing. The process chamber height (H) is varied by means of a controller (12) and an adjusting member (6), so that layers having the same layer thickness are deposited in the process chambers.

The invention relates to a method for depositing at least one layer, in particular a semiconductor layer, on a multiplicity of substrates, in which, in a coating apparatus, a plurality of process chambers, which are in particular similarly configured, are supplied with process gases by a common gas supply apparatus, the gases being introduced by, in each case, a gas inlet member into the process chamber, in which chamber one or more of the substrates to be coated are located on a susceptor, the process chamber height, which is defined by the spacing between a process chamber ceiling and a process chamber floor, being variable and influencing the growth rate of the layer.

The invention furthermore relates to apparatus for depositing at least one layer, in particular a semiconductor layer, on a multiplicity of substrates, comprising a reactor housing that has a multiplicity of substantially similarly configured process chambers, each process chamber having a gas inlet member for introducing process gases into the process chamber and a susceptor for receiving at least one substrate, and the process chamber height, which is defined by the spacing between a process chamber ceiling and a process chamber floor, being adjustable by an adjusting member, and comprising a common gas supply apparatus for supplying the process chambers with the process gas.

DE 10 2005 056 323 A1 describes an apparatus which has a reactor housing in which a plurality of process chambers are located. The apparatus also has a gas supply unit for delivering different carrier gases and process gases. The process gases are introduced in an individually metered manner into the individual process chambers via gas inlet members. For the purposes of unloading and loading, the susceptors are in this case lowerable, whereby the height of the process chamber is increased. An MOCVD process takes place in the process chambers.

DE 102 17 806 A1 describes an apparatus for carrying out an MOCVD process in which the process gases are introduced into the process chamber, in the same way as for the above-described process chamber, through a showerhead-like process inlet member. The height of the process chamber can be controlled in order to influence the growth parameters of the layers deposited there. This takes place by means of adjusting members, which can move the susceptor and a heating device fixed thereto up and down.

DE 10 2004 007 984 A1 describes a CVD-reactor in which the layer parameters determined can be determined optically during the layer growth. For this, sensors are arranged in a row in a rear wall of a gas inlet member, the optical path from the substrate to the sensor running through a gas outlet opening of the gas inlet member.

In a generic apparatus, identical growth processes can be carried out in synchronism in a plurality of process chambers.

It is an object of the invention to provide measures by which the layer thicknesses of the layers deposited in this way are substantially identical on all substrates.

Since the process chambers of a multi-process chamber reactor of this kind exhibit gradual differences, which can lead to different layer growth, individual measures must be taken for each process chamber in order to correct the layer growth. Experiments have shown that the growth rate is dependent not only on the composition and concentration of the process gases, but also on the height of the process chamber. The solution according to the invention to the above-mentioned problem consists therefore of the layer thickness being measured during the layer growth continuously or at in particular short intervals on at least one substrate in each process chamber. By means of a controller and an adjusting member, the process chamber is varied during the growth. The variation is effected with the objective of depositing, in the process chambers, layers having the same thickness. The growth rate decreases with increasing process chamber height. If for example, during the deposition process, it is determined by a layer thickness measuring device in one process chamber that the layer deposited there is instantaneously thicker than the layers that are deposited in the other process chambers, the adjusting member by which the height of the process chamber can be adjusted can therefore be acted on by the controller during the growth process by an appropriate adjusting value, so that for example the susceptor can be lowered by a certain amount so that the process chamber height is increased. As an alternative to this, the controller can also give an instruction to the adjusting members of the other process chambers to reduce the process chamber height, so that the growth rate in these increases. The choice of one or the other alternative takes place on the basis of the current process chamber height. This should not go below a prescribed minimum and should not exceed a prescribed maximum.

In a preferred elaboration of the invention, the layer thickness is determined at different locations in the process chamber and in particular at different radial distances from a center of the process chamber, which is substantially rotationally symmetrical. This is effected preferably by means of an optical measuring device, as is known from DE 10 2004 007 974 A1, namely a photo-diode array, which is disposed on the rear wall of a chamber of a gas inlet member so that the optical pathway runs in each case through a gas outlet opening on the underside of the gas inlet member. The layer thickness measuring device may however also be located outside the reactor housing. The measuring device may be connected to the process chamber via an optical fiber. It is also possible for the light for determining the layer thickness to impinge on a sensor surface through a tube.

The apparatus according to the invention is characterized by a gas supply arrangement which supplies each individual process chamber with a process gas. Individual metering units may be provided, each of which supplies a gas inlet member with process gas. The gas inlet member may be a showerhead-like body with gas exit openings disposed on the underside, through which the process gas, which is preferably an organometallic III-component and a V-hydride, is introduced into the process chamber. While the ceiling of the process chamber is formed by the underside of the gas inlet member, the floor of the process chamber is formed by the upper side of a susceptor. One or more substrates to be coated lie on the susceptor. Around the substantially circular process chamber, there extends a gas outlet ring, which is connected to a pressure regulator via a gas outlet line. All of the process chambers are connected to a common vacuum pump. Underneath the susceptor, which consists of graphite, there is a heater in order to heat the susceptor to a process temperature. The height of the susceptor, and thus the height of the process chamber, can be adjusted by means of an adjusting member. The above-mentioned layer thickness measuring device is located on the back of the gas inlet member, the device measuring the layer thickness optically during the process, through the gas outlet opening. The layer thickness measuring device may however also be provided outside the reactor housing. It may then be connected to the process chamber by means of an optical fiber. It is however also possible for the optical connection to the process chamber to be effected by way of a tube. The tube may also be purged with an inert gas. A controller is provided. This obtains input measurement values from the layer thickness measuring device. The controller compares the currently measured layer thicknesses with one another, in order to supply the adjusting member with setting values, in order to vary the process chamber height to the effect that layers with the same layer thickness are deposited.

An exemplary embodiment of the invention will be described below with reference to accompanying drawings, in which:

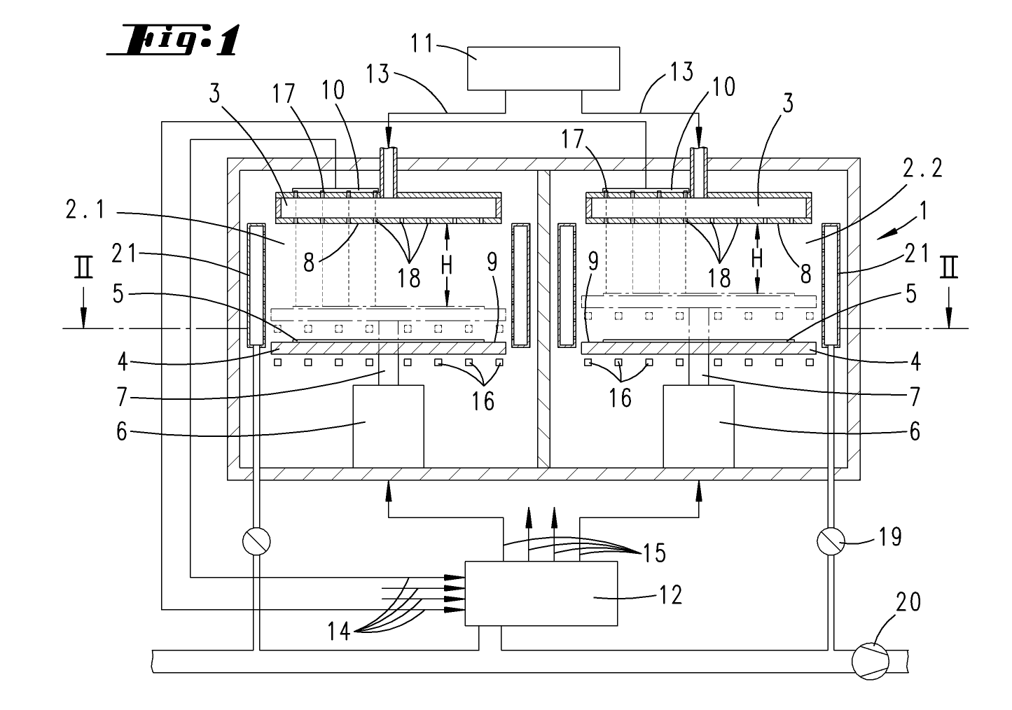

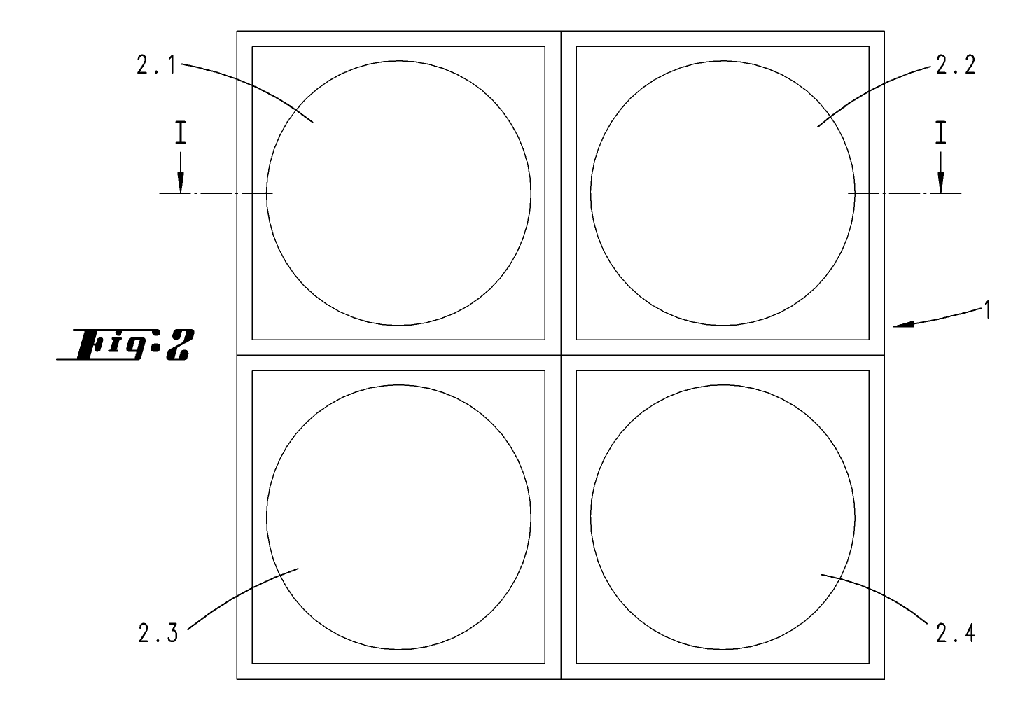

FIG. 1 shows a cross-section through a multi-process-chamber reactor along the section line I-I in FIG. 2, in schematic illustration,

FIG. 2 shows a section along the section-line II-II in FIG. 1,

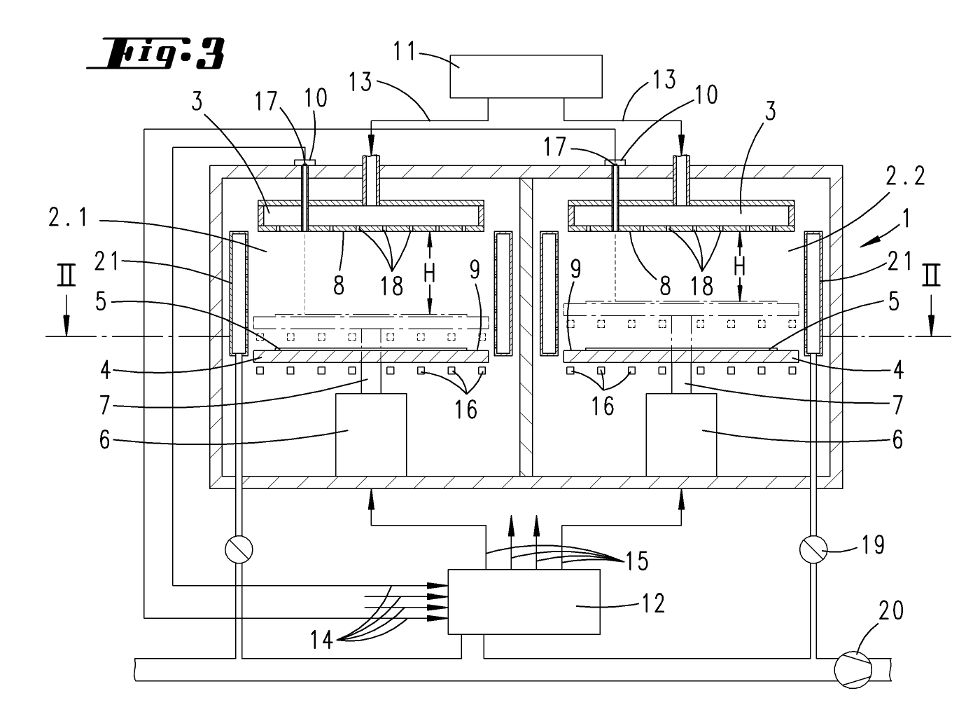

FIG. 3 shows an illustration according to FIG. 1 of another exemplary embodiment, and

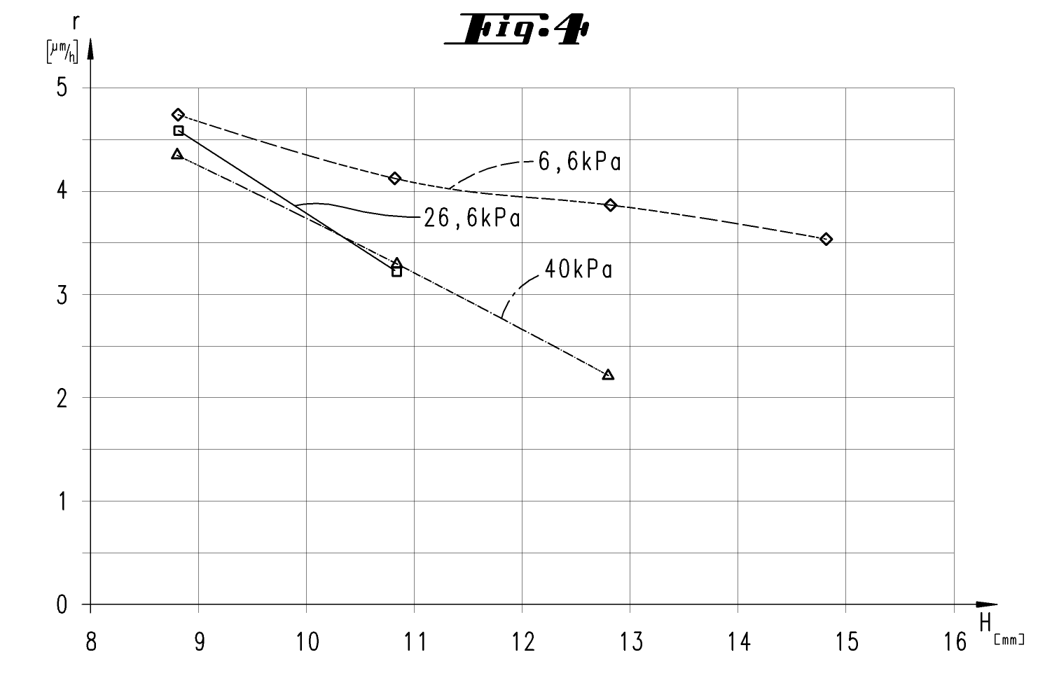

FIG. 4 shows the measured dependence of the growth rate on the process chamber height H for different total pressures.

A total of four process chambers 2.1, 2.2, 2.3 and 2.4 are formed in the reactor housing 1, which consists of stainless steel. Each of the four process chambers 2.1, 2.2, 2.3 and 2.4 is individually supplied with process gases by way of a gas feed line 13. Only one line 13 is shown for each process chamber in the figures. There may also be a plurality of feed lines 13, which however are all connected to a common gas supply apparatus 11. The gas supply apparatus 11 has valves and mass flow measuring devices, in order to meter the process gases individually.

In each of the total of four process chambers of the reactor 1, there is an inlet member 3, which has the form of a shower head. It has a rearward plate on which the optical sensor 17 and a layer thickness measuring device 10 are mounted, and a forward plate which is at a spacing from the rearward plate and in which there are a multiplicity of gas outlet openings 18. The optical pathway of the optical sensors 17 runs through some of the gas outlet openings 18. The process gas is admitted into the chamber between the back plate and the front plate of the gas inlet member 3, the process gas flowing into the process chamber 2 through the gas outlet opening 18.

A susceptor 4 is located beneath the process chamber ceiling 8 formed by the underside of the gas inlet member 3, the upper side of the susceptor forming a process chamber floor 9 that extends parallel to the process chamber ceiling 8. A substrate 5, which is coated, lies on the susceptor 4. It is however also possible to lay a plurality of substrates, which are coated at the same time, on the upper surface of the susceptor. The susceptor 4 can also be driven in rotation about a central axis.

A heater 16 is located beneath the susceptor, in order to heat the susceptor up to process temperature.

A carrier 7 is provided, which supports the heater 16 and the susceptor 4. The carrier 7 can be moved as to its height by means of an adjusting member 6, so that thereby the susceptor 4 can be raised, together with the heater 16, from the position shown in FIG. 1 in solid lines into the position shown in chain-dashed lines. This has the result that the height H of the process chamber, which corresponds to the distance between the process chamber ceiling 8 and the process chamber floor 9, is reduced.

The side wall of the process chamber 2 is formed by a gas outlet ring 21, which is connected to a pressure regulator 19 via a gas discharge line. The pressure regulator 19 may be a throttle valve. All of the throttle valves of the process chambers 2 are connected to a common vacuum pump 20.

An electronic controller 12 is provided. This receives an input value from each layer thickness measuring device 10 via a data line 14, the value corresponding to an instantaneously measured layer thickness. If the measuring device 10 has a multiplicity of optical sensors 17, the controller 12 receives a corresponding multiplicity of data. The controller 12 then determines an average layer thickness for each process chamber.

The controller 12 compares the layer thicknesses with one another and detects deviations. If the controller 12 determines that the average layer thickness in one process chamber is less than in the other process chambers, or that the average layer thickness is greater in one of the process chambers than in the other process chambers, it takes suitable measures that consist of the susceptor 4 together with the heater 16 being raised or lowered in one or more process chambers. The setting values in this regard are delivered to the respective height adjusting member 6 via data lines 15.

In a typical MOCVD process, in which a III organometallic component together with hydrogen as carrier gas and a V hydride is introduced in the low pressure region through the gas inlet member 3, the growth rate of the III-V layer decreases when the process chamber height H increases. By a displacement of the susceptor 4 upward or downward, the growth rate can thereby be modified. This is effected overall so that deposition takes place with a substantially identical layer thickness in each of the process chambers 2.1 to 2.4. The control is effected in such a way that in the individual process chambers 2.1 to 2.4, growth processes take place which are characterized by a substantially identical average growth rate. If the current growth rates in the process chambers 2.1 to 2.4 deviate from one another during the deposition process, the process chamber heights are altered. In this way, an overcompensation can take place intentionally in order to equalize a difference in the layer thicknesses.

Differing from the exemplary embodiment shown in FIG. 1, the optical sensor 17 in the exemplary embodiment shown in FIG. 3 is disposed outside the reactor housing 1. In the exemplary embodiment shown here, the optical sensor 17 is seated on the reactor housing ceiling and is connected by a tube which projects through the gas inlet member 3. The layer thickness measuring device 10 has a sensor surface which has a line-of-sight link to the substrate. Only one layer thickness measuring device 10 is shown in FIG. 3 for each process chamber 2.1, 2.2. Here also a multiplicity of layer thickness measuring devices may be provided, in order to measure the growth rate at different positions on the substrate.

In a further version which is not shown, an optical fiber is provided instead of a tube in order to establish the optical link between the optical sensor 17 and the process chamber.

In a further version, not shown, only an optical window is provided in the reactor wall, to the rear of which the optical sensor 17 is located.

Using the method according to the invention and in the apparatus according to the invention, layers of GaN, AlGaN, InGaN, GaAs, InP, AlGaAs, InGaAs etc. may be deposited. In the case of a deposition process in which GaN is deposited using TMGa and NH₃, the dependence of the growth rate r is determined by the process chamber height. FIG. 4 gives the measured values in this regard for a total pressure of 6.6 kPa, 26.6 kPa and 40 kPa. It can be seen that the growth rate (μm/h) for high total pressures has a greater dependence on the process chamber height H (mm), than for lower growth rates.

All features disclosed are (in themselves) pertinent to the invention. The disclosure content of the associated/accompanying priority documents (copy of the prior application) is also hereby included in full in the disclosure of the application, including for the purpose of incorporating features of these documents in claims of the present application. The subsidiary claims in their optional subordinated formulation characterize independent inventive refinement of the prior art, in particular to undertake divisional applications based on these claims.

### LIST OF REFERENCE NUMERALS

1 reactor housing, coating apparatus,
2 process chamber
3 gas inlet member
4 susceptor
5 substrate
6 (height) adjusting member
7 carrier
8 process chamber ceiling
9 process chamber floor
10 layer thickness measuring device
11 gas supply apparatus
12 controller
13 (gas) feed line
14 input line
15 data line
16 heater
17 optical sensor
18 (gas outlet) opening
19 pressure regulator, pressure regulation device
20 vacuum pump
21 gas outlet ring

1. A method for depositing at least one semiconductor layer on a multiplicity of substrates (5), in which, in a coating apparatus (1), a plurality of process chambers (2), which are similarly configured, are supplied with process gases by a common gas supply apparatus (11), the gases being introduced into the process chambers (2) by, in each case, a gas inlet member (3), in which chambers one or more of the substrates (5) to be coated are located on a susceptor (4), each process chamber having a height (H), which is defined by a spacing between a process chamber ceiling (8) and a process chamber floor (9), being variable and influencing a growth rate of the layer, characterized in that a layer thickness is measured during layer growth continuously or at short intervals on at least one substrate (5) in each process chamber (2) and the process chamber height (H) is varied by means of a controller (12) and an adjusting member (6) so that layers with the same layer thickness are deposited in the process chambers.

2. A method according to claim 1, characterized in that the measuring of the layer thickness is effected by an optical sensor arrangement (17), which is disposed on a rear wall of the gas inlet member (3) that forms a chamber and an optical pathway runs through, in each case, an opening (18) in the gas inlet member (3) that forms the process chamber ceiling (8).

3. A method according to any of claim 1 or 2, characterized by a common evacuation device (20) and a pressure regulating device (19) individually associated, in each case, with one of the process chambers (2).

4. A method according to any of claim 1 or 2, characterized in that an MOCVD process is carried out in the process chambers (2).

5. An apparatus for depositing at least one semiconductor layer on a multiplicity of substrates (5), comprising a reactor housing (1) that has a multiplicity of substantially similarly configured process chambers (2), each process chamber (2) having a gas inlet member (3) for introducing process gases into the process chamber (2) and a susceptor (4) for receiving at least one substrate (5), and a process chamber height (H), which is defined by a spacing between a process chamber ceiling (8) and a process chamber floor (9), being adjustable by an adjusting member (6), and further comprising a common gas supply apparatus (11) for supplying the process chambers (2) with the process gasses, characterized in that each process chamber (2) has a layer thickness measuring device (10), by which, during layer growth, a thickness of the layer on at least one substrate can be detected continuously or in short intervals, and that a controller (12) is provided, input values to which are the layer thicknesses detected by the layer thickness measuring devices (10) and output values of which are setting values for the adjusting members (6).

6. An apparatus according to claim 5, characterized by a heater (16) disposed beneath the susceptor (4), the heater being movable as to height with the susceptor (4).

7. An apparatus according to any of claims 5 or 6, characterized in that the setting values delivered by the controller (12) to the adjusting members (6) are dependent on the layer thickness measured by the layer thickness measuring device (17).

8. An apparatus according to any of claims 5 or 6, characterized in that the controller (12) is arranged so that by a variation of the process chamber height (H), layers having the same layer thickness are deposited.
